(19) United States
(12) Patent Application Publication
(10) Pub. No.: US 2023/0352275 A1
(43) Pub. Date: Nov. 2, 2023

(54) APPARATUS AND METHOD FOR PROCESSING SUBSTRATE

(71) Applicant: SEMES CO., LTD., Chungcheongnam-do (KR)

(72) Inventors: Yoon Jong Ju, Gyeonggi-do (KR); Min Sung Han, Gyeonggi-do (KR); Jae Hoo Lee, Gyeonggi-do (KR); Hyun Soo Kim, Chungcheongnam-do (KR); Seong Hak Bae, Gyeongsangnam-do (KR); Wan Jae Park, Gyeonggi-do (KR)

(21) Appl. No.: 17/733,653

(22) Filed: Apr. 29, 2022

(51) Int. Cl. H01J 37/32

(52) U.S. Cl. CPC H01J 37/3244; H01J 37/32091; H01J 2237/186

(57) ABSTRACT

A substrate processing apparatus and method for increasing substrate processing efficiency are provided. The substrate processing apparatus comprises a process chamber, in which a reaction gas is processed to have a first pressure therein, a first pumping module for pumping the process chamber to have a second pressure smaller than the first pressure, a second pumping module for pumping the process chamber to have a third pressure smaller than the second pressure, and a first automatic pressure control module for adjusting a magnitude of the second pressure by adjusting a pumping pressure of the first pumping module.

### BACKGROUND

### 1. Field

The present disclosure relates to a substrate processing apparatus and method.

### 2. Description of the Related Art

When manufacturing a semiconductor device or a display device, a substrate processing method using plasma may be used. A substrate processing process using plasma includes a capacitively coupled plasma (CCP) method, an inductively coupled plasma (ICP) method, and a method in which the two are mixed according to a method of generating plasma. In addition, dry cleaning or dry etching may be performed using plasma.

### SUMMARY

For dry cleaning of a substrate, a plasma effluent (i.e., radicals) is provided in the processing space. In addition, in order to increase the efficiency of dry cleaning, a reaction gas for generating an etchant by reacting with radicals is provided in the processing space. When the reaction gas is supplied to the processing space, process by-products due to the supply of the reaction gas into the processing space may be generated. Such process by-products may reduce the efficiency of the substrate processing apparatus.

An object of the present disclosure is to provide an apparatus and method for processing a substrate having increased efficiency by minimizing process by-products.

The objects of the present disclosure are not limited to the objects mentioned above, and other objects not mentioned will be clearly understood by those skilled in the art from the following description

One aspect of the substrate processing apparatus of the present disclosure for achieving the above object comprises a process chamber, in which a reaction gas is processed to have a first pressure therein, a first pumping module for pumping the process chamber to have a second pressure smaller than the first pressure, a second pumping module for pumping the process chamber to have a third pressure smaller than the second pressure, and a first automatic pressure control module for adjusting a magnitude of the second pressure by adjusting a pumping pressure of the first pumping module.

Wherein the first automatic pressure control module comprises a first automatic pressure control valve disposed between the process chamber and the first pumping module and a first automatic pressure control unit for controlling the first automatic pressure control valve.

The apparatus further comprises a first on-off valve interposed between the first automatic pressure control valve and the first pumping module.

The apparatus further comprises a second automatic pressure control module for adjusting a magnitude of the third pressure by adjusting a pumping pressure of the second pumping module.

Wherein the second automatic pressure control module comprises a second automatic pressure control valve disposed between the process chamber and the second pumping module and a second automatic pressure control unit for controlling the second automatic pressure control valve.

The apparatus further comprises a second on-off valve interposed between the process chamber and the second pumping module.

The apparatus further comprises a third on-off valve interposed between the first pumping module and the second pumping module.

The apparatus further comprises a temperature control module for controlling a temperature inside the second pumping module.

Wherein a temperature inside the second pumping module is 100° C. or higher.

One aspect of a dry cleaning apparatus of the present disclosure for achieving the above object comprises a process chamber, in which a reaction gas is processed, a first pumping module for pumping the process chamber to have a first pressure, a second pumping module for pumping the process chamber to have a second pressure smaller than the first pressure, and a first automatic pressure control module for adjusting a magnitude of the first pressure by adjusting a pumping pressure of the first pumping module.

Wherein the first automatic pressure control module comprises a first automatic pressure control valve disposed between the process chamber and the first pumping module and a first automatic pressure control unit for controlling the first automatic pressure control valve, and further comprises a first on-off valve interposed between the first automatic pressure control valve and the first pumping module.

The apparatus further comprises a second automatic pressure control module for adjusting a magnitude of the second pressure by adjusting a pumping pressure of the second pumping module.

Wherein the second automatic pressure control module comprises a second automatic pressure control valve disposed between the process chamber and the second pumping module and a second automatic pressure control unit for controlling the second automatic pressure control valve.

The apparatus further comprises a second on-off valve interposed between the process chamber and the second pumping module.

The apparatus further comprises a third on-off valve interposed between the first pumping module and the second pumping module.

Wherein an internal temperature of the second pumping module is 100° C. or higher.

One aspect of a substrate processing method of the present disclosure for achieving the above object comprises pumping a process chamber by a first pumping module to have a first pressure to process a reaction gas, performing a first pumping process of pumping the process chamber by the first pumping module to have a second pressure smaller than the first pressure, performing a second pumping process of pumping the process chamber by a second pumping module to have a third pressure smaller than the second pressure; and

adjusting a magnitude of the second pressure by a first automatic pressure control module for adjusting a pumping pressure of the first pumping module.

Wherein the first automatic pressure control module comprises a first automatic pressure control valve disposed between the process chamber and the first pumping module and a first automatic pressure control unit for controlling the first automatic pressure control valve.

Wherein the first pumping process is performed after the first on-off valve interposed between the first automatic pressure control valve and the first pumping module is opened, and a second pumping process of the second pumping module pumping an inside of the process chamber is performed after the first on-off valve is closed.

Wherein a magnitude of the third pressure is adjusted by a second automatic pressure control module for adjusting a pumping pressure of the second pumping module.

Another aspect of a substrate processing apparatus of the present disclosure for achieving the above object comprises a process chamber comprising a first space disposed between an electrode and an ion blocker, a second space disposed between the ion blocker and a shower head, and a processing space under the shower head for processing a substrate, wherein radicals in plasma generated in the first space pass through the ion blocker and are provided to a second space, wherein the radicals, a first reaction gas, and a second reaction gas are processed in the processing space having a first pressure therein, a first pumping module for pumping the process chamber to have a second pressure smaller than the first pressure, a second pumping module for pumping the process chamber to have a third pressure smaller than the second pressure, and a first automatic pressure control module for adjusting a magnitude of the second pressure by adjusting a pumping pressure of the first pumping module.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a view for describing a substrate processing apparatus according to some embodiments of the present disclosure;

FIG. 2 is an enlarged view of region A of FIG. 1;

FIG. 3 is a diagram illustrating a time point, at which a reaction gas is provided according to a substrate processing method according to some embodiments of the present disclosure;

FIG. 4 is a view showing the pumping module of FIG. 1 in detail;

FIG. 5 is a view showing the pressure in the processing process, in which the process by-products of FIG. 1 are generated, and the first and second pumping processes, in which the process by-products are removed;

FIG. 6 is a view showing pressures in the first and second pumping processes of FIG. 5; and

FIG. 7 is a diagram schematically illustrating a sequence of a substrate processing method according to some embodiments of the present disclosure.

### DETAILED DESCRIPTION

Hereinafter, preferred embodiments of the present disclosure will be described in detail with reference to the accompanying drawings. Advantages and features of the present disclosure and methods of achieving them will become apparent with reference to the embodiments described below in detail in conjunction with the accompanying drawings. However, the present disclosure is not limited to the embodiments described below, but may be implemented in various different forms, and these embodiments are provided only for making the description of the present disclosure complete and fully informing those skilled in the art to which the present disclosure pertains on the scope of the present disclosure, and the present disclosure is only defined by the scope of the claims. Like reference numerals refer to like elements throughout.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present disclosure.

The terminology used herein is for the purpose of describing the embodiments and is not intended to limit the present disclosure. In the present disclosure, the singular also includes the plural, unless specifically stated otherwise in the phrase. As used herein, “comprises” and/or “comprising” refers to that components, steps, operations and/or elements mentioned does not exclude the presence or addition of one or more other components, steps, operations and/or elements.

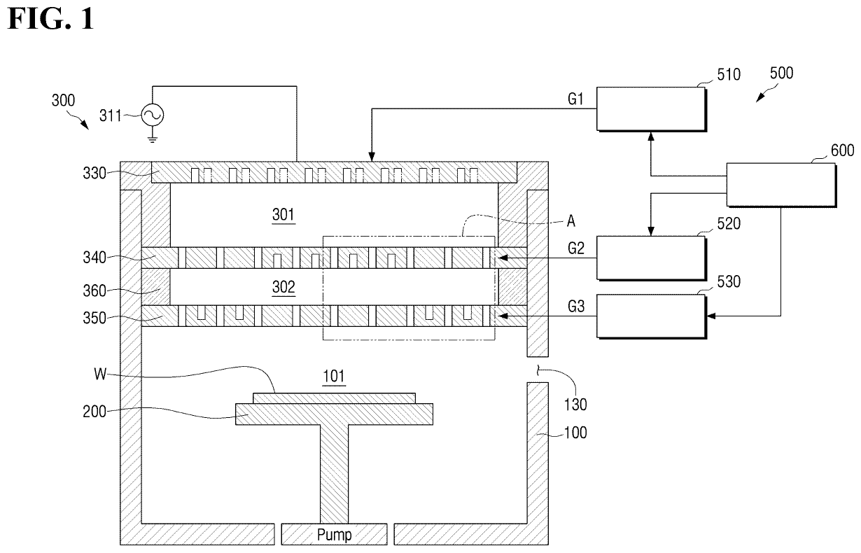

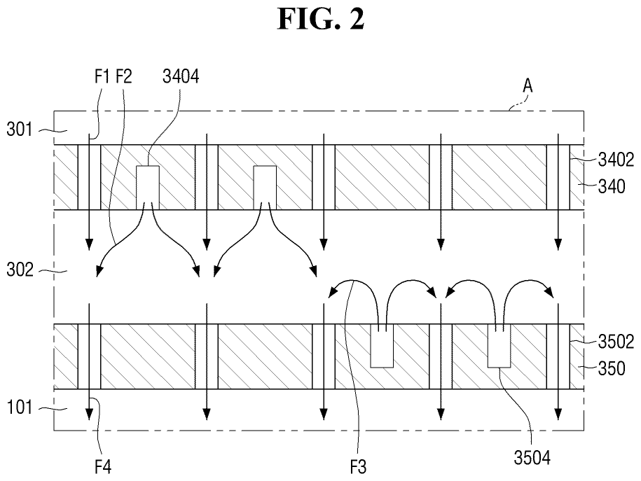

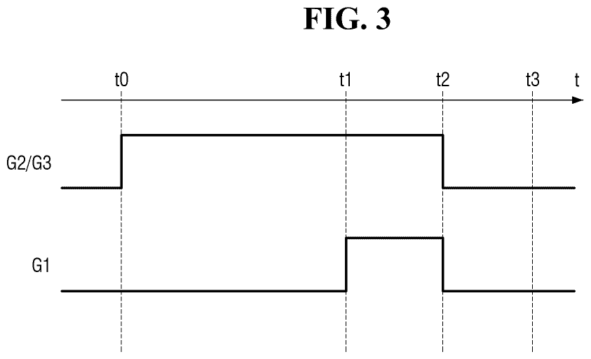

FIG. 1 is a conceptual diagram for describing a substrate processing apparatus according to some embodiments of the present disclosure. FIG. 2 is an enlarged view of region A of FIG. 1. FIG. 3 is a diagram illustrating a time point, at which a reaction gas is provided according to a method for processing a substrate according to some embodiments of the present disclosure.

Referring to FIGS. 1 to 3, a substrate processing apparatus according to some embodiments of the present disclosure comprises a process chamber 100, a support module 200, an electrode module 300, a gas supply module 500, and a control module 600, etc.

The process chamber 100 provides a processing space 101, in which the substrate W is processed. The process chamber 100 may have a circular cylindrical shape. The process chamber 100 is provided with a metal material. For example, the process chamber 100 may be provided with an aluminum material. An opening 130 is formed in one sidewall of the process chamber 100. The opening 130 is used as an entrance, through which the substrate W can be carried in and out. The entrance can be opened and closed by a door. An exhaust port (not shown) is installed on the bottom surface of the process chamber 100. The exhaust port functions as an outlet, through which by-products generated in the processing space 101 are discharged to the outside of the process chamber 100.

The support module 200 is installed in the processing space 101 and supports the substrate W. The support module 200 may be an electrostatic chuck that supports the substrate W using an electrostatic force, but is not limited thereto. The electrostatic chuck may comprise a dielectric plate, on which the substrate W is placed, an electrode installed in the dielectric plate and providing electrostatic force so that the substrate W is adsorbed to the dielectric plate, and a heater installed in the dielectric plate and controlling the temperature of the substrate W.

The electrode module 300 includes an electrode (or upper electrode) 330, an ion blocker 340, a shower head 350, a heater ring 360, and the like, and serves as a capacitively coupled plasma source. The gas supply module 500 includes a process gas supply module 510, a first reaction gas supply module 520, and a second reaction gas supply module 530. The gas supply control module 600 controls gas supply of the gas supply modules 510, 520, and 530.

A first space (i.e., a plasma generating space) 301 is disposed between the electrode 330 and the ion blocker 340, and a second space 302 is disposed between the ion blocker 340 and the shower head 350. The processing space 101 is located under the shower head 350.

The electrode 330 may be connected to a high-frequency power supply 311, and the ion blocker 340 may be connected to a constant voltage (e.g., a ground voltage). The electrode 330 includes a plurality of supply holes. The process gas supply module 510 provides the process gas G1 to the first space 301 through the electrode 330 (i.e., the supply hole of the electrode 330). The electromagnetic field generated between the electrode 330 and the ion blocker 340 excites the process gas G1 into a plasma state. The process gas excited into a plasma state (i.e., plasma effluent) contains radicals, ions and/or electrons. The process gas G1 may vary depending on the target material. The target material may be, for example, silicon oxide formed on the substrate W. In this case, the process gas G1 may be nitrogen trifluoride (NF₃), and may further include an inert gas (e.g., He).

The ion blocker 340 is formed of a conductive material, and may have, for example, a plate shape such as a disk. The ion blocker 340 may be connected to a constant voltage, but is not limited thereto. The ion blocker 340 includes a plurality of first through holes (see 3402 of FIG. 2) formed in the vertical direction. Radicals or uncharged neutral species in the plasma effluent may pass through the first through hole 3402 of the ion blocker 340. On the other hand, it is difficult for charged species (i.e., ions) to pass through the first through hole 3402 of the ion blocker 340. When the process gas G1 is nitrogen trifluoride (NF₃), fluorine-containing radicals (F*, NF₃*, etc.) may pass through the ion blocker 340.

A plurality of first supply ports 3404 for supplying the first reaction gas G2 to the second space 302 are formed in the ion blocker 340. The plurality of first supply ports 3404 may not be formed on the entire surface of the ion blocker 340, but may be formed only in a partial region.

The shower head 350 may be formed of a conductive material and may have, for example, a plate shape such as a disk. The shower head 350 may be connected to a constant voltage, but is not limited thereto. The shower head 350 includes a plurality of second through holes 3502 formed in the vertical direction.

A plurality of second supply ports 3504 for supplying the second reaction gas G3 to the second space 302 are formed in the shower head 350. The plurality of second supply ports 3504 may not be formed on the entire surface of the shower head 350, but may be formed only in a partial region.

The first reaction gas G2 and the second reaction gas G3 may vary depending on the target material and the type of the process gas G1. When the target material is silicon oxide and the process gas G1 is nitrogen trifluoride (NF₃), the first reaction gas G2 and the second reaction gas G3 may be ammonia gas (NH₃), and additionally an auxiliary gas (for example, nitrogen gas (N₂) or inert gas (He)) may be further included. The first reaction gas G2 and the second reaction gas G3 may be the same type of gas or different types of gases depending on the design. The first reaction gas G2 and the second reaction gas G3 are provided to the processing space 101 in an unexcited state (i.e., in a non-plasma state).

On the other hand, in the second space 302, radicals (e.g., fluorine-containing radicals (F*, NF₃*, etc.)) (F1) that have passed through the ion blocker 340, the first reaction gas G2 (e.g., ammonia gas) (F2) provided through the first supply port 3404 of the ion blocker 340, and the second reaction gas G3 provided through the second supply port 3504 of the shower head 350 (e.g., ammonia gas) (F3) may be collected and mixed.

The radicals (F*, NF₃*, etc.), the first reaction gas G2, and the second reaction gas G3 in the second space 302 are down flowed to the processing space 101 through the second through hole 3502 of the processing space 101 by the first pumping module 410 (F4). In particular, the second reaction gas G3 up flows into the second space 302 through the second supply port 3504 and then down flows into the processing space 101 through the second through hole 3052.

Meanwhile, the heater ring 360 may be disposed between the ion blocker 340 and the shower head 350 and surround the second space 302. The heater ring 360 is for controlling the temperature of the shower head 350 and is not installed inside the shower head 350. By installing the heater ring 360 outside the shower head 350, the shower head 350 may be slimmed down.

Hereinafter, a substrate processing process in the processing space 101 will be described in detail with reference to FIGS. 1 and 3.

Before the plasma is formed at time to, the first reaction gas G2 and the second reaction gas G3 (ammonia gas) are provided in the processing space 101 of the process chamber 100 to form a process atmosphere.

Between time t1 and time t2, a process gas G1 (nitrogen trifluoride) is provided to the first space 301. Then, the high-frequency power supply 311 is supplied to the electrode 330 to excite the process gas G1 in the form of plasma in the first space 301. Plasma effluents such as radicals, ions and/or electrons are formed. The ions may be filtered by the ion blocker 340 and the remaining plasma effluent may pass through the ion blocker 340. Plasma effluent (i.e., fluorine-containing radicals (F*, NF₃*, etc.)) passing through the ion blocker 340 is provided to the second space 302. In addition, the ion blocker 340 and the shower head 350 provide the first reaction gas G2 (i.e., ammonia gas) and the second reaction gas G3 (i.e., ammonia gas) to the processing space 101. Through the second through hole 3502 of the shower head 350, fluorine-containing radicals (F*, NF₃*, etc.) in the second space 302, the first reaction gas G2, and the second reaction gas G3 are provided to the processing space 101. In the processing space 101, fluorine-containing radicals (F*, NF₃*, etc.) react with ammonia gas (NH₃) to form an etchant (NH₄F* or NH₄F*·HF*) that can easily react with silicon oxide (SiO₂).

NH₃+NF₃*→NH₄F* or NH₄F*·HF* (Chemical Formula 1)

Then, the etchant (NH₄F* or NH₄F*·HF*) reacts with the surface of the silicon oxide formed on the substrate W. As a result of the reaction, products such as (NH₄)₂SiF₆ and H₂O may be formed. Here, H₂O is a vapor, and (NH₄)₂SiF₆ remains thin on the silicon oxide surface as a solid. The silicon (Si) in (NH₄)₂SiF₆ comes from the exposed silicon oxide, and nitrogen, hydrogen, fluorine, etc. forming the remainder come from plasma effluent, the first reactant gas G2 and/or the second reactant gas G3. During this reaction process, the temperature of the processing space 101 may be maintained at 20° C. to 100° C.

NH₄F* or NH₄F*·HF*+SiO₂→(NH₄)₂SiF₆(s)+H₂O (Chemical Formula 2)

When the temperature of the support module 200 is 100° C. or higher (e.g., 110° C.), (NH₄)₂SiF₆ is sublimated to form a gas.

From time t2 to time t3, the first and second pumping modules 410 and 420 are operated to remove by-products. Specifically, since H₂O is a vapor, it may be removed by the first and second pumping processes S21 and S22 of the first and second pumping modules 410 and 420. The temperature of the support module 200 is raised to 100° C. or higher (e.g., 110° C.) to sublimate (NH₄)₂SiF₆. Since the sublimed (NH₄)₂SiF₆ is in a gaseous state, it may be removed by the first and second pumping processes S21 and S22 of the first and second pumping modules 410 and 420.

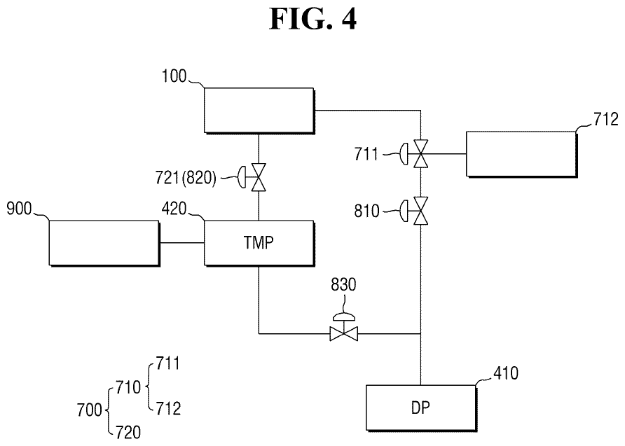

Hereinafter, a pumping module 400 used in a substrate processing apparatus according to some embodiments of the present disclosure and a substrate processing method according to some embodiments of the present disclosure will be described in detail with reference to FIGS. 4 to 7.

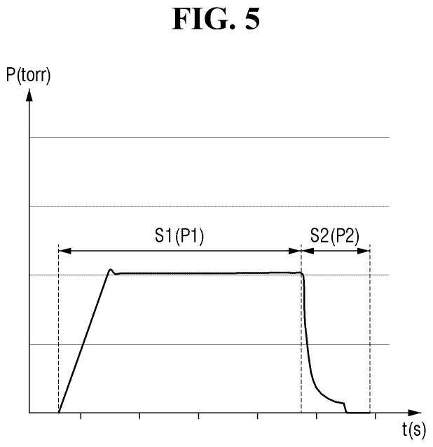

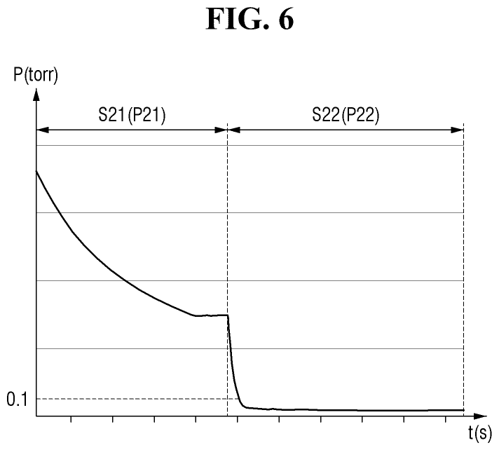

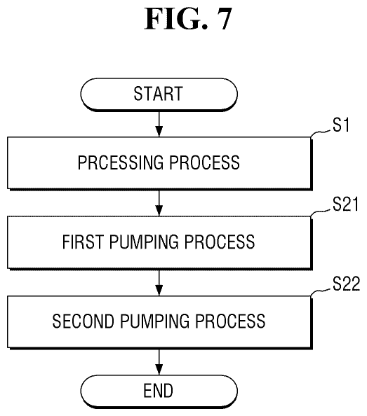

FIG. 4 is a view showing the pumping module of FIG. 1 in detail. FIG. 5 is a view showing the pressure in the processing process, in which the process by-products of FIG. 1 are generated, and the first and second pumping processes, in which the process by-products are removed. FIG. 6 is a view showing pressures in the first and second pumping processes of FIG. 5. FIG. 7 is a diagram schematically illustrating a sequence of a substrate processing method according to some embodiments of the present disclosure.

Referring to FIGS. 4 to 6, the pumping module 400 comprises a first pumping module 410 for pumping the process chamber 100 to have a second pressure P21 smaller than the first pressure P1 and a second pumping module 420 for pumping the process chamber 100 to have a third pressure P22 smaller than the second pressure P21. In this embodiment, the first pumping module 410 may mean a low vacuum pump, and, for example, a dry pump may be used. Also, in this embodiment, the second pumping module 420 may mean a high vacuum pump, and, for example, a turbo molecular pump (TMP) may be used.

Specifically, the afore-mentioned radicals (F*, NF₃*, etc.), the first reaction gas G2, and the second reaction gas G3 may be processed within the processing space 101 by pumping the process module 100 by the first pump to have a first pressure P1. Thereafter, a first pumping process S21 of pumping the process chamber 100 by the first pumping module 410 to have a second pressure P21 smaller than the first pressure P1 is performed. Thereafter, a second pumping process S22 of pumping the process chamber 100 by the second pumping module 420 to have a third pressure P22 smaller than the second pressure P21 is performed. That is, after the processing process (S1) and the first pumping process (S21) are finished, the second pumping process may be performed (S22) in the final pumping step or in the step, in which the substrate W is released from the support module 200.

In a conventional substrate processing apparatus, only a low vacuum pump is generally used as a means for adsorbing process by-products. In this case, it is difficult to provide a low pressure to sufficiently adsorb the process by-products, and thus there is a problem in that it is difficult to completely remove the process by-products. In this embodiment, after the first pumping process (S21) by the first pumping module 410, which is a low vacuum pump, is performed, the second pumping process (S22) by the second pumping module 420, which is a high vacuum pump, is performed. As a result, it is possible to minimize adsorption of process by-products into the substrate or the process chamber. In addition, since there is no need to use a separate annealing apparatus for removing process by-products, the substrate processing apparatus and method may be more efficient. Meanwhile, although the processing process is described as a dry cleaning process in this embodiment, the processing process may be an etching process or a deposition process. As described above, since the processing process S1, and the first and second pumping processes S12 and S22 are repeatedly performed in one cycle, process by-products can be more effectively removed.

Referring to FIG. 4, a first automatic pressure control (APC) module 710 that adjusts the magnitude of the second pressure P21 by adjusting the pumping pressure of the first pumping module 410 is included. The first automatic pressure control module 710 comprises the first automatic pressure control valve 711 disposed between the process chamber 100 and the first pumping module 410 and a first automatic pressure control unit 712 that controls the first automatic pressure control valve 711. That is, in a region where the inside of the process chamber 100 has a second pressure P21 that is relatively higher than the third pressure P22, the pumping pressure of the first pumping module 410 can be controlled by the first automatic pressure control module 710.

In the present embodiment, when pumping using the first pumping module 410, the process may be performed while controlling the pressure through the automatic pressure control valve 711. As a result, it is possible to more precisely control the pumping pressure of the first pumping module 410.

In addition, in this embodiment, the first on-off valve 810 interposed between the first automatic pressure control valve 711 and the first pumping module 410 is further included.

Referring to FIG. 4, a second automatic pressure control module 720 for adjusting the magnitude of the third pressure P22 by adjusting the pumping pressure of the second pumping module 420 is further included. The second automatic pressure control module 720 comprises the second automatic pressure control valve 721 disposed between the process chamber 100 and the second pumping module 410 and a second automatic pressure control unit (not shown) that controls the second automatic pressure control valve 721. The pumping pressure of the second pumping module 420 may be controlled by the second automatic pressure control module 720 so that the inside of the process chamber 100 has a third pressure P22 that is a low pressure. In addition, in this embodiment, the second on-off valve 820 interposed between the process chamber 100 and the second pumping module 420 is further included. In the present embodiment, when pumping using the second pumping module 420, the process may be performed while controlling the pressure through the automatic pressure control valve 721. As a result, the pumping pressure of the second pumping module 420 may be more precisely controlled.

Meanwhile, the substrate processing apparatus according to the present embodiment may selectively include a second automatic pressure control valve 721 and a second on-off valve 820.

In addition, in this embodiment, a third on-off valve 830 interposed between the first pumping module 410 and the second pumping module 420 is further included.

Specifically, after the first on-off valve 810 interposed between the first automatic pressure control valve 711 and the first pumping module 410 is opened, the first pumping process S21 is performed. Thereafter, the first on-off valve 810 is closed and a second pumping process S22, in which the second pumping module 420 pumps the inside of the process chamber 100, is performed. The first pumping process S21 may not be performed simultaneously with the second pumping process S22. The first pumping process S21 is not performed while the third on-off valve 830 is open. That is, the first on-off valve 810 may not open at the same time as the third on-off valve 830.

The internal temperature of the second pumping module 420 may be 100° C. or higher. The second pumping module 420 may be designed to respond to a high temperature of 100° C. or higher. As described above, when the temperature of the support module 200 is 100° C. or higher, the process by-product is sublimated to form a gas. Referring to FIG. 3, process by-products may be removed by operating the first and second pumping modules 410 and 420 from t2 to t3. Since the sublimated process by-product is in a gaseous state, it may be removed by the first and second pumping processes S21 and S22.

In this embodiment, a temperature control module 900 for controlling the internal temperature of the second pumping module 420 may be further included. Although not specifically shown, the temperature control module 900 may further include a heating member (not shown) for heating the inside of the second pumping module 420. The temperature control module may heat a heating member (not shown) so that the internal temperature of the second pumping module 420 is 100° C. or higher.

Although embodiments of the present disclosure have been described with reference to the above and the accompanying drawings, those skilled in the art, to which the present disclosure pertains, can understand that the present disclosure may be practiced in other specific forms without changing its technical spirit or essential features. Therefore, it should be understood that the embodiments described above are illustrative in all respects and not limiting.

What is claimed is:

1. An apparatus for processing a substrate comprising:
a process chamber, in which a reaction gas is processed to have a first pressure therein;
a first pumping module for pumping the process chamber to have a second pressure smaller than the first pressure;
a second pumping module for pumping the process chamber to have a third pressure smaller than the second pressure; and
a first automatic pressure control module for adjusting a magnitude of the second pressure by adjusting a pumping pressure of the first pumping module.

2. The apparatus of claim 1, wherein the first automatic pressure control module comprises a first automatic pressure control valve disposed between the process chamber and the first pumping module and a first automatic pressure control unit for controlling the first automatic pressure control valve.

3. The apparatus of claim 2 further comprises,
a first on-off valve interposed between the first automatic pressure control valve and the first pumping module.

4. The apparatus of claim 1 further comprises,
a second automatic pressure control module for adjusting a magnitude of the third pressure by adjusting a pumping pressure of the second pumping module.

5. The apparatus of claim 4, wherein the second automatic pressure control module comprises a second automatic pressure control valve disposed between the process chamber and the second pumping module and a second automatic pressure control unit for controlling the second automatic pressure control valve.

6. The apparatus of claim 1 further comprises,
a second on-off valve interposed between the process chamber and the second pumping module.

7. The apparatus of claim 1 further comprises,
a third on-off valve interposed between the first pumping module and the second pumping module.

8. The apparatus of claim 1 further comprises,
a temperature control module for controlling a temperature inside the second pumping module.

9. The apparatus of claim 1, wherein a temperature inside the second pumping module is 100° C. or higher.

10. An apparatus for dry cleaning comprising:
a process chamber, in which a reaction gas is processed;
a first pumping module for pumping the process chamber to have a first pressure;
a second pumping module for pumping the process chamber to have a second pressure smaller than the first pressure; and
a first automatic pressure control module for adjusting a magnitude of the first pressure by adjusting a pumping pressure of the first pumping module.

11. The apparatus of claim 10, wherein the first automatic pressure control module comprises a first automatic pressure control valve disposed between the process chamber and the first pumping module and a first automatic pressure control unit for controlling the first automatic pressure control valve, and further comprises a first on-off valve interposed between the first automatic pressure control valve and the first pumping module.

12. The apparatus of claim 10 further comprises,
a second automatic pressure control module for adjusting a magnitude of the second pressure by adjusting a pumping pressure of the second pumping module.

13. The apparatus of claim 12, wherein the second automatic pressure control module comprises a second automatic pressure control valve disposed between the process chamber and the second pumping module and a second automatic pressure control unit for controlling the second automatic pressure control valve.

14. The apparatus of claim 12 further comprises,
a second on-off valve interposed between the process chamber and the second pumping module.

15. The apparatus of claim 10 further comprises,
a third on-off valve interposed between the first pumping module and the second pumping module.

16. The apparatus of claim 10, wherein an internal temperature of the second pumping module is 100° C. or higher.

17. A method for processing a substrate comprising:
pumping a process chamber by a first pumping module to have a first pressure to process a reaction gas;
performing a first pumping process of pumping the process chamber by the first pumping module to have a second pressure smaller than the first pressure;
performing a second pumping process of pumping the process chamber by a second pumping module to have a third pressure smaller than the second pressure; and
adjusting a magnitude of the second pressure by a first automatic pressure control module for adjusting a pumping pressure of the first pumping module.

18. The method of claim 17, wherein the first automatic pressure control module comprises a first automatic pressure control valve disposed between the process chamber and the first pumping module and a first automatic pressure control unit for controlling the first automatic pressure control valve.

19. The method of claim 18, wherein the first pumping process is performed after a first on-off valve interposed between the first automatic pressure control valve and the first pumping module is opened,
wherein a second pumping process of the second pumping module pumping an inside of the process chamber is performed after the first on-off valve is closed.

20. The method of claim 17, wherein a magnitude of the third pressure is adjusted by a second automatic pressure control module for adjusting a pumping pressure of the second pumping module.
